(19) United States
(12) Patent Application Publication
(10) Pub. No.: US 2025/0031317 A1
(43) Pub. Date: Jan. 23, 2025

(54) METHOD FOR MOUNTING AN ELECTRONIC DEVICE ON A FLEXIBLE SUBSTRATE AND AN ELECTRONIC PACKAGE

(71) Applicant: JCET STATS ChipPAC Korea Limited, Incheon (KR)

(72) Inventors: SeungHyun LEE, Incheon (KR); Heesoo LEE, Incheon (KR)

(21) Appl. No.: 18/765,342

(22) Filed: Jul. 8, 2024

(30) Foreign Application Priority Data
Jul. 18, 2023 (CN) 202310879734.0

(51) Int. Cl. H05K 3/34; H05K 1/18

(52) U.S. Cl. CPC H05K 3/341; H05K 1/181; H05K 1/189; H05K 3/3463; H05K 3/3494; H05K 2201/0129; H05K 2201/10098

(57) ABSTRACT

A method for mounting an electronic device on a flexible substrate is disclosed. The method comprising: providing the flexible substrate with conductive patterns on its front surface; forming solder bumps on the conductive patterns; dispensing a thermosetting material on the front surface of the flexible substrate; attaching the electronic device on the flexible substrate via the solder bumps and the thermosetting material; heating the flexible substrate to a first temperature to cure the thermosetting material; and heating the flexible substrate to a second temperature higher than the first temperature to reflow the solder bumps.

### TECHNICAL FIELD

The present application generally relates to semiconductor packaging technology, and more particularly, to a method for mounting an electronic device on a flexible substrate.

### BACKGROUND OF THE INVENTION

The semiconductor industry is constantly faced with complex integration challenges as consumers want their electronics to be smaller, faster and higher performance with more and more functionality packed into a single device.

SMT, known as Surface Mount Technology, is a popular device mounting technology and process in the electronic packaging industry. It is a packaging technology that installs surface mounted components or devices (SMC/SMDs) without pins or short leads on the surface of printed circuit boards (PCBs) or other substrates, and assembles them by reflowing solder materials that are deposited on the PCBs in advance.

However, it is noted that when the SMC/SMDs are mounted on a flexible substrate such as a polymide strip, false welding may often occur, especially for large-sized SMC/SMCs, which leads to a lower yield and reliability for electronic packages assembled using the SMT process.

Therefore, a need exists for further improvement to the conventional SMT process.

### SUMMARY OF THE INVENTION

An objective of the present application is to provide a surface mounting method with high reliability.

According to an aspect of the present application, a method for mounting an electronic device on a flexible substrate is disclosed. The method comprises: providing the flexible substrate with conductive patterns on its front surface; forming solder bumps on the conductive patterns; dispensing a thermosetting material on the front surface of the flexible substrate; attaching the electronic device on the flexible substrate via the solder bumps and the thermosetting material; heating the flexible substrate to a first temperature to cure the thermosetting material; and heating the flexible substrate to a second temperature higher than the first temperature to reflow the solder bumps.

According to another aspect of the present application, a method for mounting an electronic device on a flexible substrate, the method comprising: providing the flexible substrate with conductive patterns on its front surface; forming solder bumps on the conductive patterns; dispensing a thermosetting material on a bottom surface of the electronic device; attaching the bottom surface of the electronic device on the front surface of the flexible substrate via the solder bumps and the thermosetting material; heating the flexible substrate to a first temperature to cure the thermosetting material; and heating the flexible substrate to a second temperature higher than the first temperature to reflow the solder bumps.

According to another aspect of the present application, an electronic package is disclosed, which is made using the methods according to the above aspects of the present application.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates three states of an antenna package made by a conventional SMT process.

FIG. 2 illustrates three states of an antenna package made by a method for mounting an electronic device on a flexible substrate according to an embodiment of the present application.

FIGS. 3A to 3F are side views illustrating various steps of a method for mounting an electronic device on a flexible substrate according to an embodiment of the present application.

FIGS. 4 and 5 illustrate two other exemplary layouts of thermosetting material that may be formed on flexible substrates for maintaining the attachment between a flexible substrate and an electronic device mounted thereon.

FIGS. 6A to 6J illustrate various steps of a method for making an electronic package are illustrated according to an embodiment of the present application.

FIGS. 7A to 7I illustrate various steps of a method for making an electronic package are illustrated according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, it is noted by the inventors of the present application that when SMC/SMDs are mounted on a flexible substrate using conventional SMT processes, false welding may often occur, especially for large-sized SMC/SMCs.

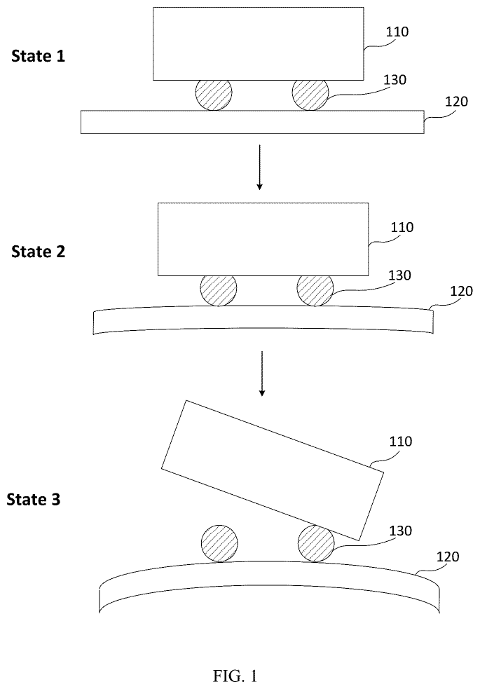

FIG. 1 illustrates three states of an antenna package made by a conventional SMT process. As shown in FIG. 1, in state 1, an antenna module 110 is attached onto a flexible substrate 120 via solder bumps 130. Under room temperature, the flexible substrate 120 may not deform so the attachment between the antenna module 110 and the flexible substrate 120 is good. However, a reflow operation is desired to be performed to the flexible substrate 120 and the solder bumps 130 to melt the solder bumps 130 for better metallurgical connection. During the reflow operation, the temperature of the antenna package may increase following a predetermined heating profile. In particular, in state 2 when the temperature increases from room temperature to a value which is not sufficiently high, for example, lower than a melting temperature of the solder material of the solder bumps 130, the flexible substrate 120 may deform or warp a little due to a mismatch in coefficient of thermal expansion (CTE) between the antenna module 110 and the flexible substrate 120. In state 2, since the solder bumps 130 do not melt, the antenna module 110 can still be well connected with the flexible substrate 120, without undesired movement relative to the flexible substrate 120. As the reflow operation goes on and the temperature increases, for example, to a value higher than the melting temperature of the solder bumps 130, the solder bumps 130 start to melt. At the same time, due to the significant mismatch in CTE between the antenna module 110 and the flexible substrate 120, especially in case that the flexible substrate 120 is much thinner and more flexible than the antenna module 110, the flexible substrate 120 may bow significantly, resulting in a shear force that may detach the antenna module 110 from the flexible substrate 120 at some of the melted solder bumps 130. In other words, false welding occurs between the antenna module 110 and the flexible substrate 120, which leads to a lower yield and reliability of the antenna package.

To address the above problem, the inventors of the present application proposed a new method for mounting an electronic device on a flexible substrate. In particular, a thermosetting material is introduced between the electronic device and the flexible substrate, which can fix the electronic device on the flexible substrate before the solder bumps start to melt during the reflow operation. The thermosetting material may have a thermosetting characteristic, i.e., curable at a thermosetting temperature. The thermosetting temperature of the thermosetting material can be lower than a melting temperature of solder bumps. As such, while the solder bumps have not melted, the thermosetting material may have already been cured and solidified, and thus is capable of holding the electronic device firmly on the flexible substrate.

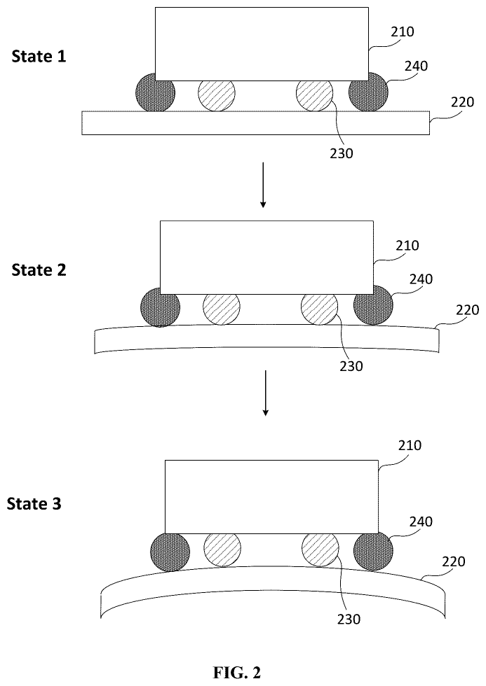

FIG. 2 illustrates three states of an antenna package made by a method according to an embodiment of the present application. As shown in FIG. 2, in state 1, an antenna module 210 is attached onto a flexible substrate 220 via solder bumps 230 and a thermosetting material 240. Then, a reflow operation is performed to the flexible substrate 220 and the solder bumps 230 to melt the solder bumps 230. The temperature for the reflow operation increases gradually. In state 2 when the temperature is not sufficiently high but reaches a thermosetting temperature of the thermosetting material 240, the flexible substrate 220 may warp a little. At the same time, the thermosetting material 240 is cured and thus solidified. As such, the antenna module 210 can be well connected with the flexible substrate 220. As the reflow operation goes on and the temperature reaches a melting temperature of the solder bumps 230, the solder bumps 230 start to melt. Different from state 3 of the antenna package shown in FIG. 1, even if the flexible substrate 220 may bow significantly, the antenna module 210 cannot be detached from the flexible substrate 220 because they are firmly connected with each other through the solidified thermosetting material 240. As such, the conductive patterns such as conductive pads of the antenna module 210 and the flexible substrate 220 may not move relative to each other even if the solder bumps 230 melt, and thus false welding may not occur.

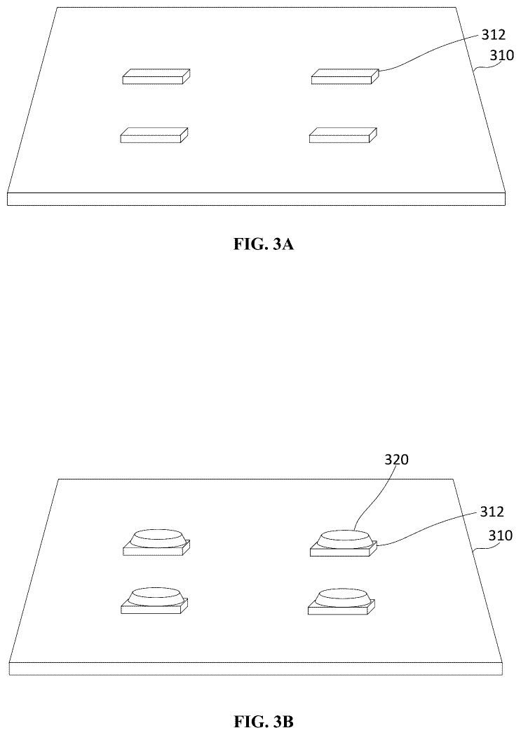

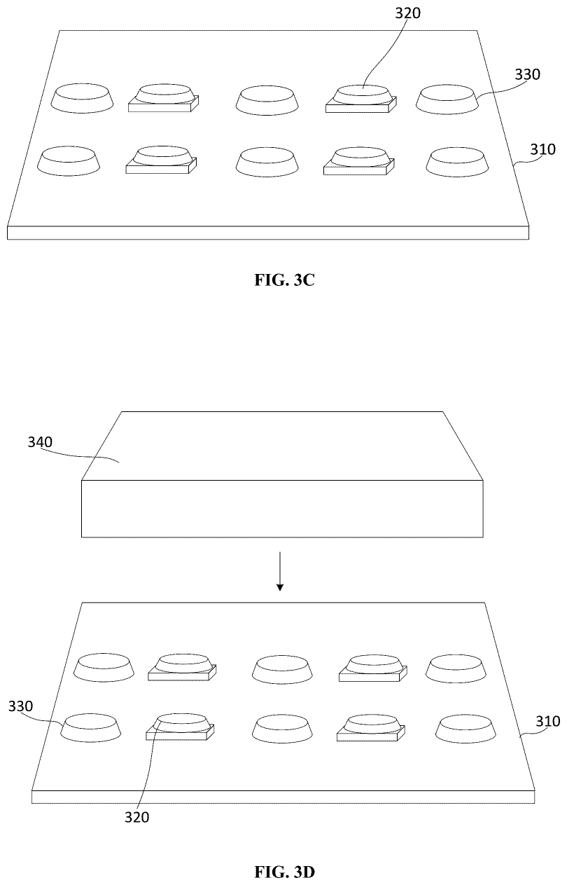

Referring to FIGS. 3A to 3F, side views illustrating various steps of a method for mounting an electronic device such as an antenna module on a flexible substrate are illustrated.

As illustrated in FIG. 3A, a flexible substrate 310 such as a polyimide film is provided. The flexible substrate 310 may include various conductive patterns 312 such as contact pads on its front surface. The flexible substrate 310 may also include one or more dielectric layers and one or more conductive layers between and through the dielectric layers. The conductive layers may define pads, traces and plugs through which electrical signals or voltages can be distributed horizontally and vertically. In some embodiments, the flexible substrate 310 may be much thinner than the electronic device to be amounted thereon. For example, the flexible substrate 310 may have a thickness of less than 30% of that of the electronic device to be mounted, or less than 10% of that of the electronic device to be mounted.

Next, as illustrated in FIG. 3B, solder bumps 320 may be formed on the flexible substrate 310. In an example, solder paste may be printed over the respective conductive patterns 312 on the front surface of the flexible substrate 310 to form the solder bumps 320. Thus, the solder bumps 320 may have a layout the same as that of the conductive patterns 312.

In some alternative embodiments, the solder bumps 320 can be formed on the flexible substrate 310 using one of or any combination of the following processes: evaporation, electrolytic plating, electroless plating, ball drop, or screen printing process. The solder paste material can be Al, Sn, Ni, Au, Ag, lead (Pb), bismuth (Bi), Cu, or any combinations thereof, with an optional flux solution. In some embodiments, the solder bumps 320 may take the form of a ball bump, a stud bump, a micro bump, or any other similar shapes. It can be appreciated that the solder bumps 320 may be reflowed by being heated to or above its melting temperature.

Next, as illustrated in FIG. 3C, after the solder bumps 320 are formed, a thermosetting material 330 such as epoxy may be dispensed on the front surface of the flexible substrate 310, for example, by dipping or printing. In some embodiments, the thermosetting material 330 may be dispensed in the form of dots, lines, or other suitable shapes. Preferably, the thermosetting material 330 may be formed in a planar layout, for example, the layout of thermosetting material 330 may include three or more dots that are not arranged in a single line. It can be appreciated that the layout of the thermosetting material 330 is generally coplanar with a layout of the solder bumps 320 such that the thermosetting material 330 can maintain the alignment and attachment between the flexible substrate 310 and the electronic device to be mounted.

The thermosetting material 330 may be dispensed close to or near each of the solder bumps 320, so that the electronic device to be mounted later can cover both the thermosetting material 330 and the solder bumps 320. For example, the thermosetting material 330 may be dispensed between two adjacent solder bumps 320, or may be dispensed around the solder bumps 320. In some embodiments, at least some of the thermosetting material 330 may be dispensed on the flexible substrate 310 outside of the entire layout of the solder bumps 320. Preferably, the thermosetting material 330 may have a dimension smaller than a distance of two adjacent solder bumps 320 so that the thermosetting material 330 may not adhere to the solder bumps 320 during a subsequent reflow operation to the solder bumps 320.

Next, as illustrated in FIG. 3D, an electronic device 340 may be mounted on the front surface of the flexible substrate 310. The electronic device 340 may have underneath conductive patterns (not shown) that can be connected to the conductive patterns of the flexible substrate 310 via the respective solder bumps 320. In some embodiments, the electronic device 340 can be an antenna module. The antenna module may include antennas packaged in an encapsulant mold, for example. It can be seen that the thermosetting material may be dispensed in a layout that is generally aligned with a periphery of the electronic device 340.

Afterwards, a reflow operation may be performed to the flexible substrate 310 as well as the components and electronic device attached thereon. The reflow operation may gradually increase a temperature of the flexible substrate 310. As shown in FIG. 3E, the temperature of the flexible substrate 310 may reach a first temperature to cure the thermosetting material 330. For example, the first temperature may be higher than a thermosetting temperature of the thermosetting material 33, but may be lower than a melting temperature of the solder bumps 320. As such, the thermosetting material 330 may be cured and solidified, thereby providing a firm attachment of the electronic device 340 to the flexible substrate 310. It can be appreciated that the first temperature may depend on the thermosetting characteristic of the thermosetting material 330. In an example where the thermosetting material 330 is epoxy, the first temperature may range 110 to 180 centi-degrees, or preferably 110 to 140 centi-degrees. In some embodiments, the temperature of the flexible substrate 310 may be maintained at the first temperature for a predetermined period, e.g., longer than 30 seconds, longer than 2 minutes, longer than 5 minutes, or longer than 15 minutes, to allow for complete thermosetting of the thermosetting material 330. At this point, since the temperature of the flexible substrate 310 has not reached the melting temperature of the solder bumps 320, the solder bumps 320 may not be melted. Therefore, even if the flexible substrate 310 warps or even bows later, the solidified thermosetting material 330 can hold the electronic device 340 firmly with the flexible substrate 310.

Afterwards, the reflow operation continues. As shown in FIG. 3F, the temperature of the flexible substate 310 increases to a second temperature to reflow the solder bumps 320. The second temperature is higher than the first temperature, and in particular, higher than the melting point of the solder bumps 320. The solder bumps 320 start to melt, while the thermosetting material 330 still works to hold the electronic device 340. After the solder bumps 320 get cured and return to solidify, the flexible substrate 310 and the electronic device 340 are more firmly assembled with each other. The combination of the solder bumps 320 and the thermosetting material 330 effectively avoids the formation of false welding due to warpage of the flexible substrate 310 at the high reflow temperature.

It can be appreciated that although the thermosetting material is formed on the flexible substrate in the embodiment shown in FIGS. 3A to 3F, in some alternative embodiments, the thermosetting material can be dispensed on a surface (e.g., a bottom surface) of the electronic device through which the electronic device is connected with the front surface of the flexible substrate. It can be appreciated that the thermosetting material needs to avoid the conductive patterns of the flexible substrate and the electronic device when it is dispensed.

Various layouts of thermosetting material can be dispensed on a flexible substrate. In some examples, the layout of thermosetting material may depend on the form factors of the electronic device and/or the layout of the solder bumps between the electronic device and the flexible substrate.

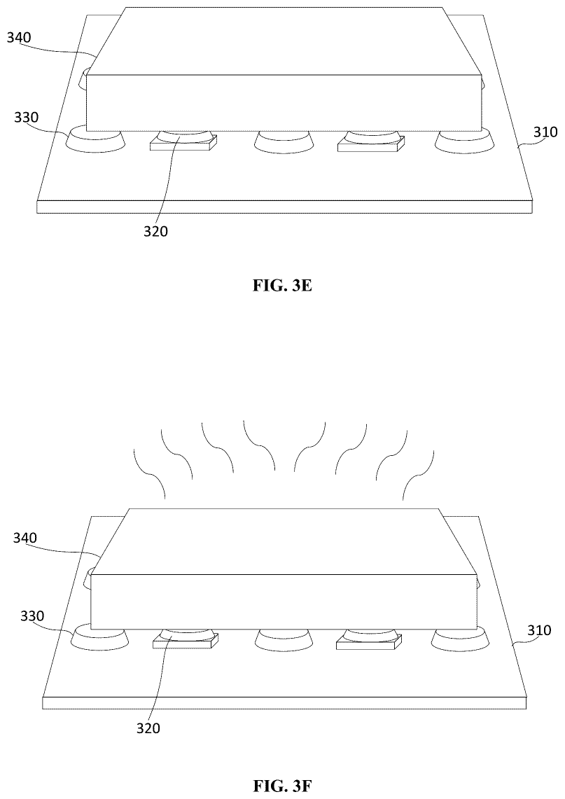

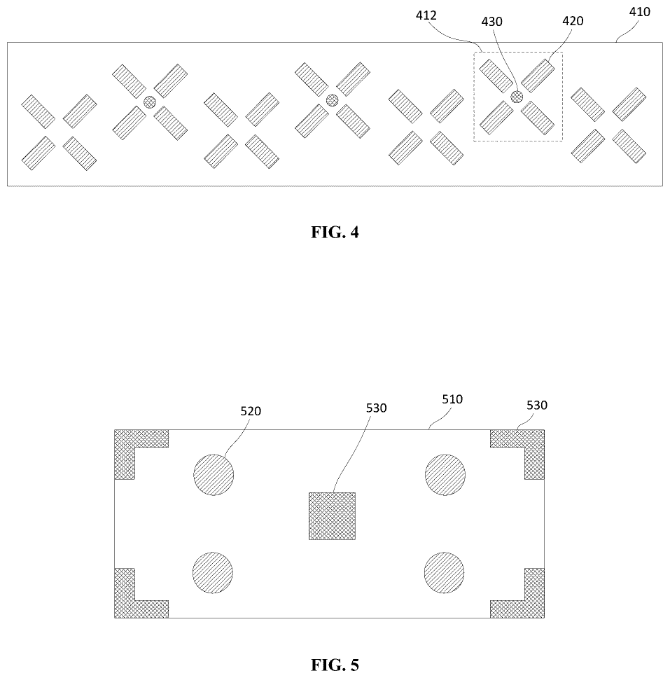

FIGS. 4 and 5 illustrate two other exemplary layouts of thermosetting material that may be formed on flexible substrates for maintaining the attachment between a flexible substrate and an electronic device mounted thereon.

As illustrated in FIG. 4, a top view of a flexible substrate strip 410 is provided. The flexible substrate strip 410 may have several repeated sets of conductive patterns 412 on its front surface. Solder paste may be printed or otherwise deposited on the conductive patterns 412 to form solder bumps 420 for further attachment of an electronic device (not shown). In the embodiment, a thermosetting material may be dispensed on the front surface of the flexible substrate strip 410 at respective centers of some sets of conductive patterns 412. The thermosetting material may take the form of dots, for example. Therefore, multiple dots of thermosetting material may be distributed generally across the front surface of the flexible substrate strip 410. In this way, during a reflow operation for the solder bumps, the thermosetting material which has been cured before the melting of the solder bumps can maintain the electronic device firmly on the flexible substrate 410. It can be appreciated that three or more dots of the thermosetting material 430 can provide better attachment compared with one or two dots.

In another example as illustrated in FIG. 5, a top view of a flexible substrate 510 is provided. The flexible substrate 510 has a set of conductive patterns on its front surface. Solder bumps 520 may be formed on the respective conductive patterns. In addition, a thermosetting material 530 may be dispensed on the front surface of the flexible substate 510 at four corners and the center of the flexible substrate 510 to surround the solder bumps 520. Such planar layout of thermosetting material 530 can ensure firm attachment of an electronic device to the flexible substrate 510 whether the flexible substrate 510 warp in any manners.

A shear test is performed on electronic packages made using the method according to some embodiments of the present application and using the conventional method. A shear test machine model Dage-4000 is used, which can provide a shear speed of 700 um/s and a maximum shear force of 5 kgF. The shear force is gradually applied the electronic packages. Table 1 below shows the test results of the shear test.

TABLE 1
Shear Test Results

| | | Solder Bumps + |
|---|---|---|
| | | Thermosetting Material |
| | Only Solder | (Examples of |
| | Bumps (Conventional | The Present |
| | Method) | Application) |
| SN# | Shear Strength | Shear Strength |
| Min | 734.8 gF | Over 5 kgF |
| Max | 852.9 gF | |
| Avg | 790.8 gF | |

As shown in Table 1, for the electronic packages made using the conventional method, they can only resist an average shear strength of 790.8 gF. However, for the electronic packages made using the method of the present application, they can resist a shear strength over 5 kgF. It can be seen that the solder welding of the electronic packages made using the method of the present application is significantly better, which improves the reliability of the electronic packages.

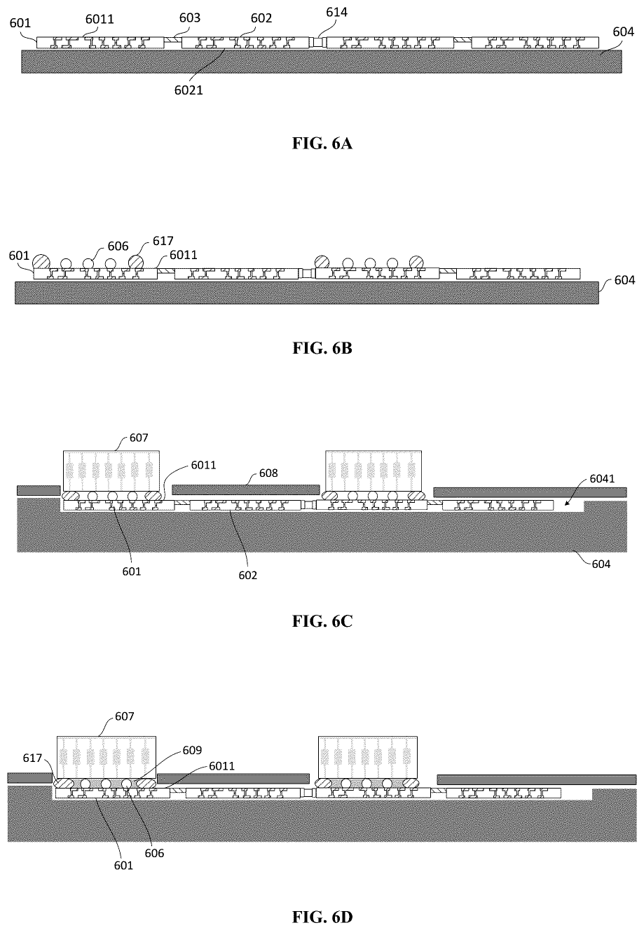

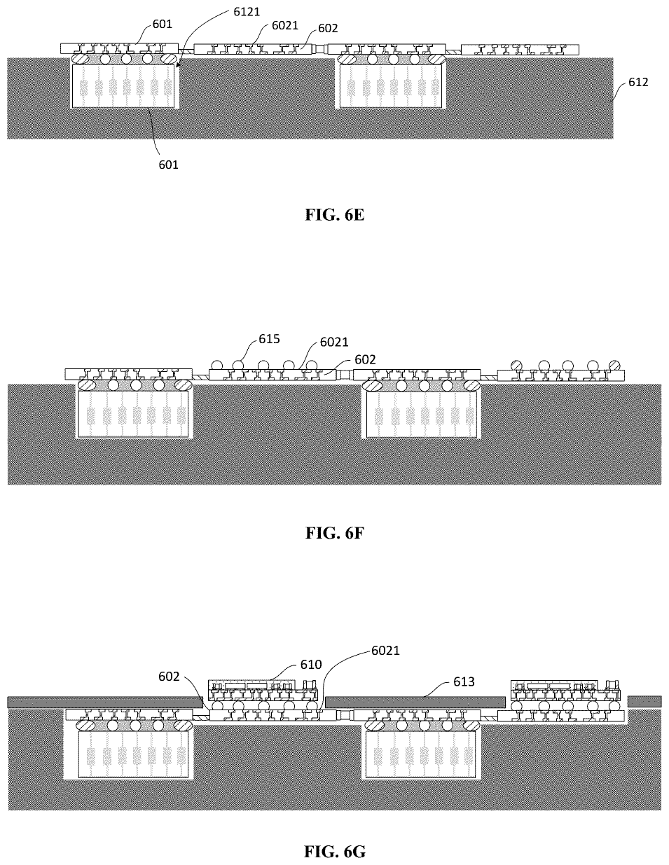

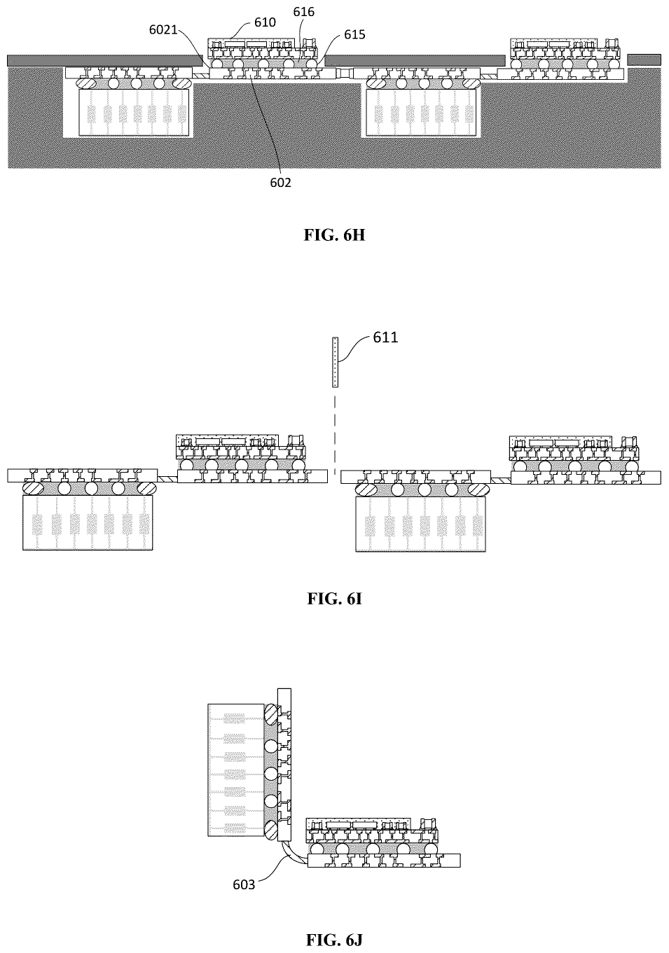

The method for mounting electronic devices of the present application may be implemented in the manufacturing of various electronic packages. Referring to FIGS. 6A to 6J, various steps of a method for making an electronic package are illustrated according to an embodiment of the present application.

As shown in FIG. 6A, a substrate strip including a plurality of substrate assemblies is provided. In some embodiments, the plurality of substrate assemblies of the substrate strip may be arranged in a row and connected together as a chain. In some other embodiments, the plurality of substrate assemblies of the substrate strip may be arranged in an array with multiple rows and columns. In this way, the plurality of substrate assemblies can be processed simultaneously to improve the efficiency of the manufacturing process.

In the embodiment shown in FIG. 6A, the substrate strip includes two substrate assemblies which are separated from each other by a singulation channel 614. The singulation channel 614 can provide a cutting area to singulate the substrate strip into two individual substrate assemblies. In some embodiments, the singulation channel 614 can be made of a rigid material. In some alternative embodiments, the singulation channel 614 can be made of a flexible material, such as polyimide or other similar polymeric materials. Since the singulation channel 614 needs to be cut or in other manners broken in a subsequent step, it is preferred that the singulation channel 614 is made of a material that is easily cut, for example, using a laser ablation process.

Each substrate assembly includes a first substrate 601, a second substrate 602, and a flexible link 603 disposed between the first substrate 601 and the second substrate 602. The first substrate 601 and the second substrate 602 may be rigid printed circuit boards (PCB) or flexible printed circuit boards (FPC).

Various electronic devices can be mounted onto the first substrate 601 and the second substrate 602. Specifically, the first substrate 601 includes a first mounting surface 6011 and the second substrate 602 includes a second mounting surface 6021 that is not at the same side of the substrate assembly as the first mounting surface 6011. As shown in FIG. 6A, when the substrate strip is disposed on a first carrier 604 such as a metal or glass carrier, the first mounting surface 6011 of the first substrate 601 is facing away from the first carrier 604, i.e., oriented in an upward direction, and the second mounting surface 6021 of the second substrate 602 is facing towards the first carrier 604, i.e., oriented in a downward direction. One or more signals may be transmitted over the flexible link 603, including but limited to power signals and control signals. In some embodiments, the signals are transmitted over one or more separate wires or cables of the flexible link 603, and the signal transmission in the flexible link 603 can be bi-directional. For example, the flexible link 603 may be a flex cable or flexible circuit board.

Afterwards, as shown in FIG. 6B, a plurality of solder bumps 606 are formed over the first mounting surface 6011 of each first substrate 6011. The solder bumps 606 can be formed using one of or any combination of the following process: evaporation, electrolytic plating, electroless plating, ball drop, or screen-printing process. The conductive bump material can be Al, Sn, Ni, Au, Ag, lead (Pb), bismuth (Bi), Cu, or combinations thereof, with an optional flux solution. For example, the bump material can be eutectic Sn/Pb, high-lead solder, or lead-free solder. In an embodiment, the bump material may be reflowed by heating the material above its melting temperature to form conductive balls or bumps.

Furthermore, after the solder bumps 606 are formed, a thermosetting material 617 such as epoxy may be dispensed on the first mounting surface 6011 of each first substrate 6011, for example, by dipping or printing. Preferably, the thermosetting material 617 may be formed in a planar layout, for example, at four corners of the first substrate 6011 outside the solder bumps 606. It can be appreciated that the layout of the thermosetting material 617 is generally coplanar with a layout of the solder bumps 606 such that the thermosetting material 617 can maintain the alignment and attachment between the first substrate 6011 and an electronic device to be mounted.

Afterwards, as shown in FIG. 6C, a first electronic device 607 is attached onto the first mounting surface 6011 of each first substrate 601. In some embodiments, before attaching the first electronic devices 607, a first substrate mask 608 having a plurality of first openings is disposed onto the first mounting surface 6011 of the first substrate 601. Each first opening is aligned with the first substrate 601 of a substrate assembly, to expose the first mounting surface 6011 of the first substrate 601. In this way, the first electronic device 607 can be precisely mounted onto the first mounting surface 6011 of the first substrate 601 through the corresponding first opening. At the same time, the second substrate 602 can be covered by the first substrate mask 608 during the attaching process.

In some embodiments, the first electronic device 607 may be an antenna module mounted onto the first substrate 601. In some embodiments, the antenna may be a dielectric resonator antenna (DRA) including dielectric resonators and antenna feed. Dielectric resonators are provided for transmitting and receiving millimeter wave antenna signals with different frequencies and/or communication protocols, which are generally made of materials with low loss and high dielectric constant, for example, the dielectric resonators may be made of polymer materials. In some embodiments, the dielectric resonator antenna is designed as any three-dimensional shape, including cylinder, rectangle, sphere or ring, for example. The antenna module may have a thickness that is significantly greater than that of the first substrate 601.

In some embodiments, the first substrate mask 608 is a metal cover made of a metal material (e.g., stainless steel, aluminum, etc.) or any other suitable material (e.g., plastics), or a combination of these materials to prevent substrate warpage during the attaching process. The first substrate mask 608 can be removed from the substrate strip after the attaching process. In this way, the first substrate mask 308 can be reused for other substrate strips for mounting the first electronic devices on the respective first substrates. However, for those substrates that are not covered by the first substrate mask 608, the substrate warpage may not be avoided.

In some embodiments, the first carrier 604 may include a substrate strip cavity 6041 for receiving the substrate strip. The substrate strip cavity 6041 has a depth greater than the height of the substrate strip to accommodate the substrate strip in whole. As such, the first substrate mask 608 can be supported by the first carrier 604, without being in direct contact with the substrate strip and potential contamination to the surfaces of the substrate strip.

A reflow operation may be performed to the substrate strip as well as the components and electronic devices attached thereon. The reflow operation may gradually increase a temperature of the first substrates 601. The temperature of the first substrates 601 may reach a first temperature to cure the thermosetting material 617. For example, the first temperature may be higher than a thermosetting temperature of the thermosetting material 617, but may be lower than the melting temperature of the solder bumps 606. As such, the thermosetting material 617 may be cured and solidified, thereby providing a firm attachment of the electronic device 607 to the first substrate 601. In some embodiments, the temperature of the first substrate 601 may be maintained at the first temperature for a predetermined period to allow for complete thermosetting of the thermosetting material 617. At this point, since the temperature of the first substrates 601 has not reached the melting temperature of the solder bumps 606, the solder bumps 606 may not be melted. Therefore, even if the first substrates warp or even bow later, the solidified thermosetting material 617 can hold the electronic device 607 firmly with the first substrate 601.

The reflow operation continues. The temperature of the first substates 601 increases to a second temperature to reflow the solder bumps 606. The solder bumps 606 start to melt, while the thermosetting material 617 still works to hold the electronic devices 607. After the solder bumps 606 get cured and return to solidify, the first substrates 601 and the electronic devices 607 are more firmly assembled with each other.

Next, an encapsulant 609 such as an underfill material is injected into a gap between the first electronic device 607 and the first mounting surface 6011 of the first substrate 601 to ensure that the encapsulant 609 fully fills the space surrounding the plurality of solder bumps 606.

As shown in FIG. 6E, the first substrate mask 608 is removed from the first carrier 604. Then, the substrate strip is flipped over and disposed on a second carrier 612 with a plurality of cavities 6121. As such, the first mounting surface 6011 of each first substrate 601 is facing towards the second carrier 612, i.e., oriented downwards, and the second mounting surface 6021 of the second substrate 602 is facing away from the second carrier 612, i.e., oriented upwards. Accordingly, the first substrate 601 may substantially cover the opening of a cavity 6121, with its periphery supported by an edge of the cavity 6121. In this way, the first substrate 601 can be at the same level as the second substrate 602, which facilitates further processing (e.g., solder printing) to the substrate strip.

As can be seen in FIG. 6E, since the cavities 6121 of the second carrier 612 accommodate the raised structures (i.e., the first electronic devices) at one side of the substrate strip, a substantially flat profile can be formed at the other side of the substrate strip during the manufacturing process, therefore mass production can be implemented on the various substrate assemblies at the same time.

Afterwards, as shown in FIG. 6F, a plurality of solder bumps 615 are formed over the second mounting surface 6021 of the second substrate 602, and the plurality of bumps 615 as shown in FIG. 6F may have the same or similar structure as the plurality of bumps 606 shown in FIG. 6B, which will not be elaborated herein. In the embodiment, the thermosetting material is not dispensed on the second substrate 602, but in some other embodiments, the thermosetting material may be dispensed around the solder bumps 615 in a manner similar as the thermosetting material on the first substrate.

As shown in FIG. 6G, a second electronic device 610 is attached onto the second mounting surface 6021 of the second substrate 602. In some embodiments, similar as the first substrate mask 608, a second substrate mask 613 having a plurality of second openings is also disposed onto the second mounting surface 6021 of the second substrate 602, with each second opening aligned with the second substrate 602 of a substrate assembly. The second opening can expose the second mounting surface 6021. Next, the second electronic device 610 is mounted onto the second mounting surface 6021 of the second substrate 602 through the corresponding second opening.

As shown in FIG. 6H, each second electronic device 610 is mounted onto the respective second mounting surface 6021 via the plurality of solder bumps 615. For example, the corners of the second electronic device 610 may be pressed against the solder bumps 615. Next, an encapsulant 616 can be injected into a gap between the second electronic device 610 and the second mounting surface 6021 of the second substrate 602 to ensure the encapsulant 616 fully fills the space surrounding the bumps 615. The encapsulant 616 is cured or heated after the injection.

As shown in FIG. 61, the second substrate mask is removed from the second carrier 612 and the substrate strip can be unloaded from the second carrier 612. Then the substrate strip can be singulated into various substrate assemblies at the respective singulation channels. Specifically, the substrate strip as shown in FIG. 6I can be singulated into the substrate assemblies using a laser ablation tool 611. In some embodiments, a mechanical saw blade also can be used to mechanically singulate the singulation channels. After that, the flexible link 603 of each substrate assembly may be bended and cured, to form the electronic package with its two substrates substantially perpendicular to each other, as shown in FIG. 6J.

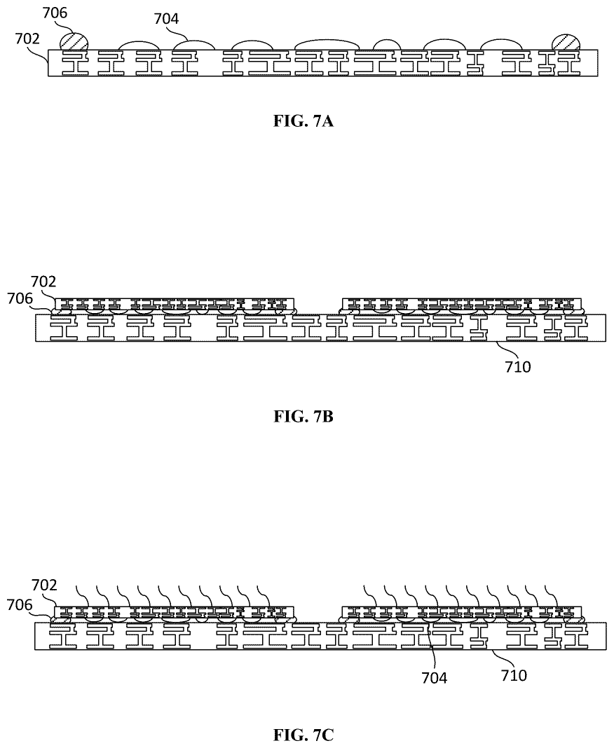

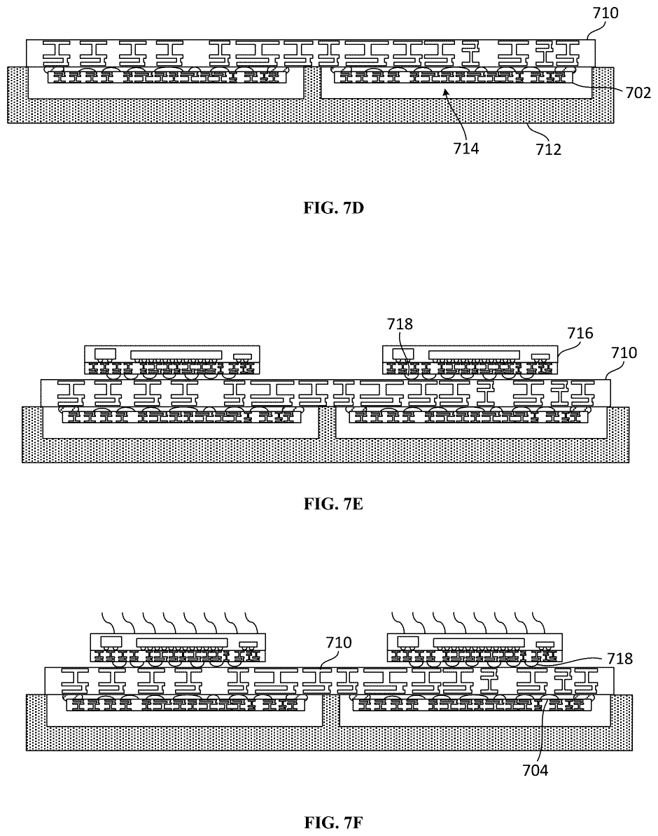

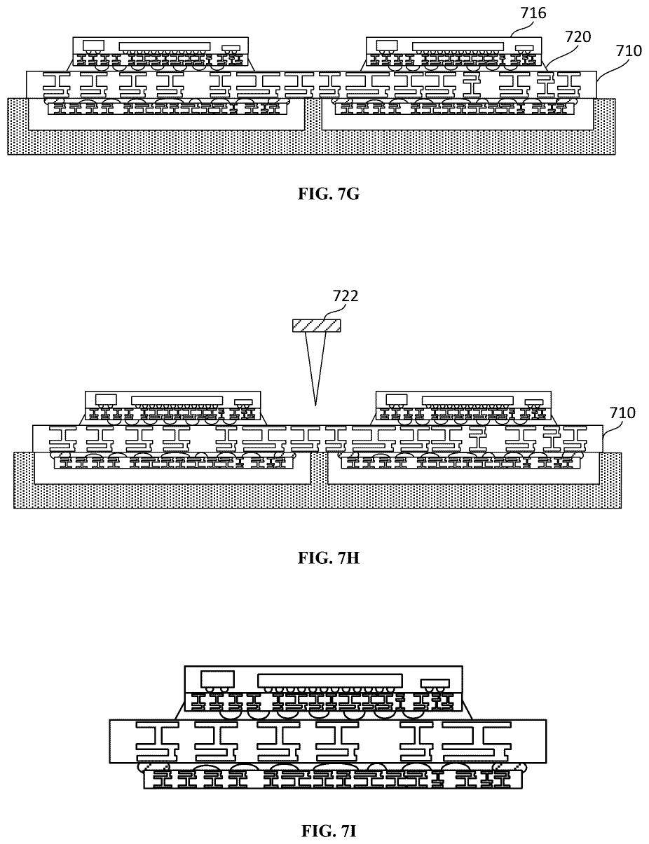

FIGS. 7A to 7I are side views illustrating various steps of a method for making an electronic package according to another embodiment of the present application.

As shown in FIG. 7A, a first substrate 702 is provided, which may be a rigid substrate. Solder bumps 704 may be formed on the first substrate 702, and a thermosetting material 706 may be further dispensed on the first substrate 702. It can be appreciated that multiple first substrates 702 may be formed similarly with the corresponding solder bumps 704 and thermosetting material 706.

Next, as shown in FIG. 7B, the first substrates 702 may be mounted on a substrate strip 710 which may be a flexible substrate strip. The solder bumps 704 and the thermosetting material 706 may be in contact with the substrate strip 710 to support the first substrates 702 thereon.

As shown in FIG. 7C, a reflow operation may be performed to the substrate strip 710 as well as the first substrates 702 attached thereon. The reflow operation may gradually increase a temperature of the first substrates 702 and the substrate strip 710. The temperature of the first substrates 702 may reach a first temperature to cure the thermosetting material 706. As such, the thermosetting material 706 may be cured and solidified, thereby providing a firm attachment of the first substrates 702 to the substrate strip 710. Since the first substrates 702 can be attached to the substrate strip 710 via the solidified thermosetting material 706, it is not desired to reflow the solder bumps 704 at this stage. It can be appreciated that the thermosetting temperature of the thermosetting material 706 may not be very high so that the warpage of the flexible substrate strip 710 may not be significant.

Next, as shown in FIG. 7D, the substrate strip 710 may be flipped over and disposed on a carrier 712. The carrier 712 has cavities to accommodate the substrates 702 respectively. As such, other components or substrates may be further mounted on the substrate strip 710 at a different side. In particular, as shown in FIG. 7E, multiple second substrates 716 may be mounted on the substrate strip 710, while each of the second substrates 716 may have certain electronic devices mounted thereon. In other words, the second substrates 716 may be preformed before they are mounted on the substrate strip 710, and therefore they may have a greater thickness due to its complicated structure such as devices, encapsulants, etc., and a relatively greater rigidness. However, since the first substrates 702 have already been mounted on the substrate strip 710, the warpage of the substrate strip 710 can be inhibited by the first substrates significantly. In some embodiments as shown in FIG. 7E, the second substrates 716 may be mounted on the substrate strip 710 without the thermosetting material, but in some other embodiments, the second substrates 716 may be mounted on the substrate strip 710 with both the thermosetting material and the solder bumps 718.

Next, as shown in FIG. 7F, a reflow operation for the solder bumps 704 and 718 on both sides of the substrate strip 710 may be performed. In some embodiments where the solder bumps 704 and 718 may be made of the same solder material, the reflow operation may be performed at a temperature greater than a melting temperature of the solder material of the solder bumps 704 and 718. In some other embodiments where the solder bumps 704 and 718 may be made of different solder materials, the reflow operation may be performed at a temperature greater than melting temperatures of the solder materials of the solder bumps 704 and 718. Nevertheless, the solder bumps 704 and 718 can be cured after the reflow operation.

After the reflow operation has completed, an underfill material 720 may be formed between the second substrates 716 and the substrate strip 710 to reinforce their connection, as shown in FIG. 7G. Afterwards, the substrate strip 710 can be singulated into individual electronic packages at respective singulation channels, for example, using a laser ablation tool 722, as shown in FIG. 7H. In this way, an electronic package like that shown in FIG. 7I can be made.

The discussion herein included numerous illustrative figures that showed various portions of a method for mounting an electronic device on a flexible substrate. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for mounting an electronic device on a flexible substrate, the method comprising:
providing the flexible substrate with conductive patterns on its front surface;
forming solder bumps on the conductive patterns;
dispensing a thermosetting material on the front surface of the flexible substrate;
attaching the electronic device on the front surface of the flexible substrate via the solder bumps and the thermosetting material;
heating the flexible substrate to a first temperature to cure the thermosetting material; and
heating the flexible substrate to a second temperature higher than the first temperature to reflow the solder bumps.

2. The method of claim 1, wherein dispensing a thermosetting material on the front surface of the flexible substrate comprises:
dispensing the thermosetting material in a planar layout.

3. The method of claim 2, wherein the planner layout comprises three or more dots that are not arranged in a single line.

4. The method of claim 1, wherein dispensing a thermosetting material on the front surface of the flexible substrate comprises:
dispensing the thermosetting material between the two adjacent conductive patterns covered with the solder bumps.

5. The method of claim 1, wherein dispensing a thermosetting material on the front surface of the flexible substrate comprises:
dispensing the thermosetting material around the conductive patterns covered with the solder bumps.

6. The method of claim 1, wherein dispensing a thermosetting material on the front surface of the flexible substrate comprises:
dispensing the thermosetting material in a layout that is aligned with a periphery of the electronic device.

7. The method of claim 1, wherein the first temperature is higher than a thermosetting temperature of the thermosetting material but lower than a melting temperature of the solder bumps.

8. The method of claim 1, wherein the electronic device is an antenna module.

9. An electronic package made using the method of claim 1.

10. A method for mounting an electronic device on a flexible substrate, the method comprising:
providing the flexible substrate with conductive patterns on its front surface;
forming solder bumps on the conductive patterns;
dispensing a thermosetting material on a bottom surface of the electronic device;
attaching the bottom surface of the electronic device on the front surface of the flexible substrate via the solder bumps and the thermosetting material;
heating the flexible substrate to a first temperature to cure the thermosetting material; and
heating the flexible substrate to a second temperature higher than the first temperature to reflow the solder bumps.

11. An electronic package made using the method of claim 10.
